(19) United States
(12) Patent Application Publication
(10) Pub. No.: US 2016/0254300 A1
(43) Pub. Date: Sep. 1, 2016

(54) SENSOR FOR DUAL-APERTURE CAMERA

(71) Applicant: DUAL APERTURE INTERNATIONAL CO., LTD., Seongnam-si (KR)

(72) Inventors: Andrew Wajs, Haarlem (NL); David Lee, Palo Alto, CA (US); Keunmyung Lee, Palo Alto, CA (US); Haeseung Lee, Lexington, MA (US); Jongho Park, Daejeon (KR)

(73) Assignee: DUAL APERTURE INTERNATIONAL CO., LTD., Seongnam-si (KR)

(21) Appl. No.: 14/956,337

(22) Filed: Dec. 1, 2015

Related U.S. Application Data
(60) Provisional application No. 62/121,147, filed on Feb. 26, 2015.

(51) Int. Cl. H01L 27/146; H04N 5/225

(52) U.S. Cl. CPC H01L 27/14607; H04N 5/2254; H01L 27/14647; H01L 27/14652

(57) ABSTRACT

a sensor system for a dual-aperture camera. The sensitivity of infrared (IR) light may be increased in order to reduce the noise of an image. For example, the size of an infrared pixel may be increased with respect to visible light pixels. For example, an infrared pixel may be stacked below a visible light pixel or pixels. For example, a separate infrared pixel may be provided as a second source of infrared light.

This patent application claims priority to U.S. Provisional Patent Application No. 62/121,147 filed on Feb. 26, 2015, which is hereby incorporated by reference in its entirety.

### BACKGROUND

U.S. patent application Ser. No. 13/144,499 relates a dual-aperture camera having two apertures. The first aperture is a relatively narrow aperture for a first wavelength range (e.g. infrared light spectrum) to produce a relatively sharp image across the entire image. The second aperture is a relatively wide aperture for second wavelength range (e.g. a visible light spectrum) to produce a focused image that is sharp at the focus point of the image, but progressively blurry at distances away from the focus point of the image. U.S. patent application Ser. No. 13/579,568 relates to blur comparison between two corresponding images of a dual-aperture camera to determine three dimensional distance information or depth information of an object depicted in the images or pixels of the images. This principle may be extended to multiple apertures where either a coded aperture is used for a single region of the light spectrum or each region of the light spectrum has its own aperture.

Because the first aperture for infrared light is smaller than the aperture for visible light, the amount of infrared light that passes through the smaller first aperture is less than the amount of visible light that passes through the larger second aperture.

There are multiple ways of increasing the relative level of the infrared sensitivity. Dual-aperture cameras and methods such as those disclosed in U.S. patent application Ser. No. 13/579,568 disclose varying different ISO and or exposure time settings for each component, particularly allowing for a different infrared exposure or ISO setting. However, notwithstanding related art methods, there remains a need for increasing the infrared sensitivity in dual aperture cameras.

### SUMMARY

Embodiments relate to a dual aperture camera that uses two different sized apertures for two different wavelength ranges for image enhancement and/or measuring depth of the depicted objects in the image. Embodiments relate to a sensor system for a dual-aperture camera that enhance the infrared sensitivity. In embodiments, the sizes and arrangements of pixels, including infrared and visible pixels, are different. In embodiments, the infrared pixels and visible light pixels are stacked over each other. In embodiments, additional infrared pixels are provided in order to receive more infrared light.

### DRAWINGS

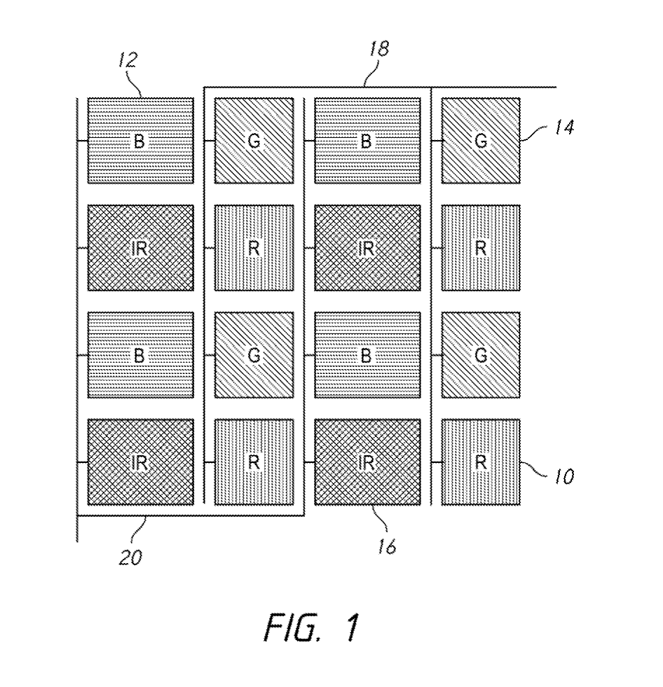

Example FIG. 1 illustrates infrared pixels with different sizes from some of the visible light pixels, in accordance with embodiments.

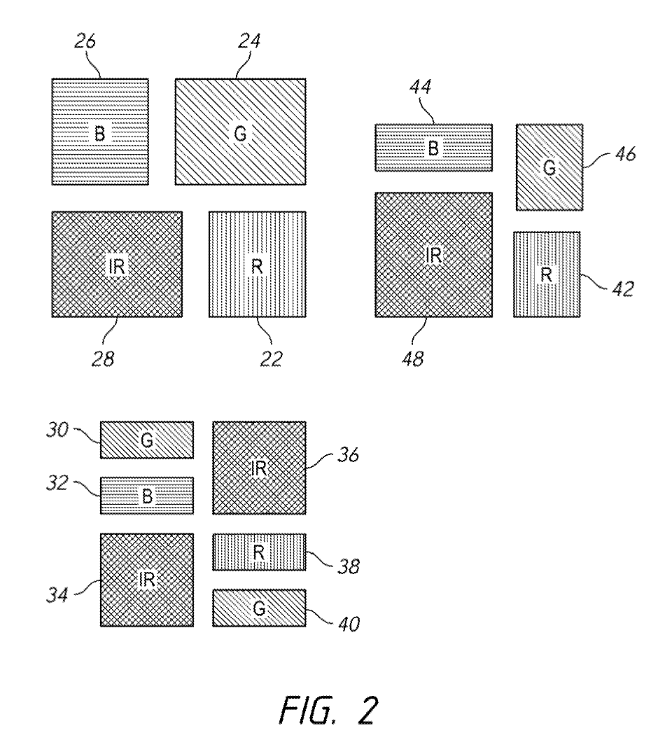

Example FIG. 2 illustrates different patterns of infrared and visible light pixels having different pixel sizes, in accordance with embodiments.

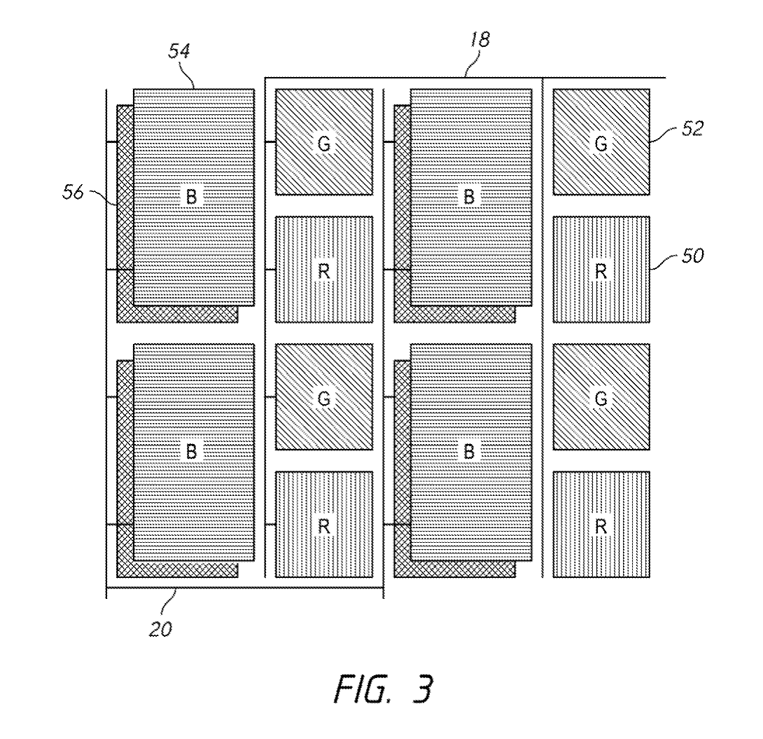

Example FIG. 3 illustrates a blue pixel stacked over an infrared pixel, in accordance with embodiments.

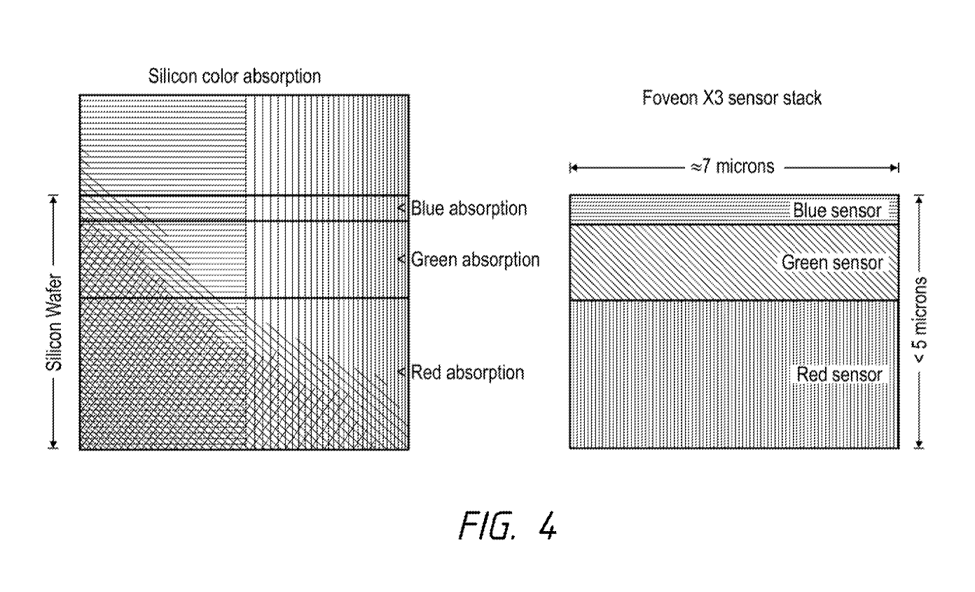

Example FIG. 4 illustrates light penetration in a Foveon-type image sensor, in accordance with embodiments.

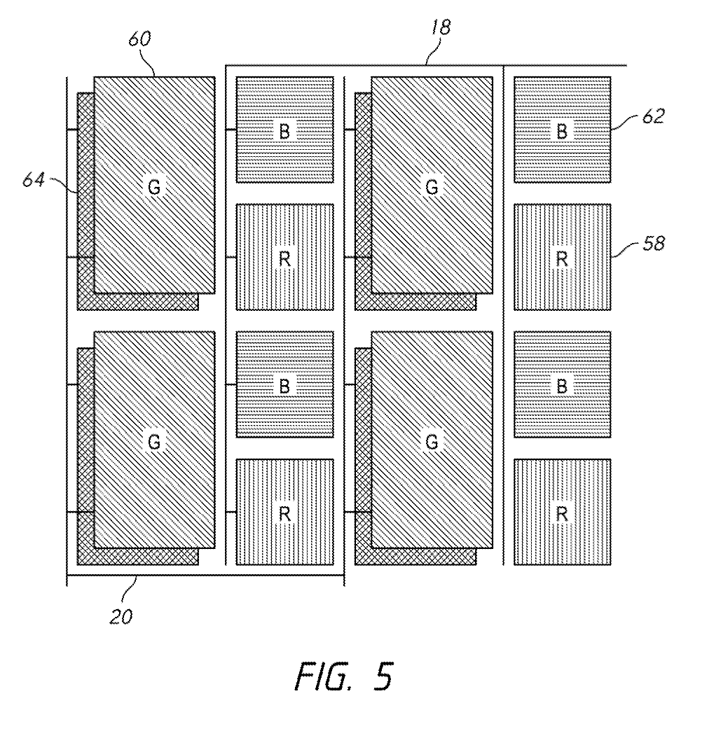

Example FIG. 5 illustrates a green pixel stacked over an infrared pixel, in accordance with embodiments.

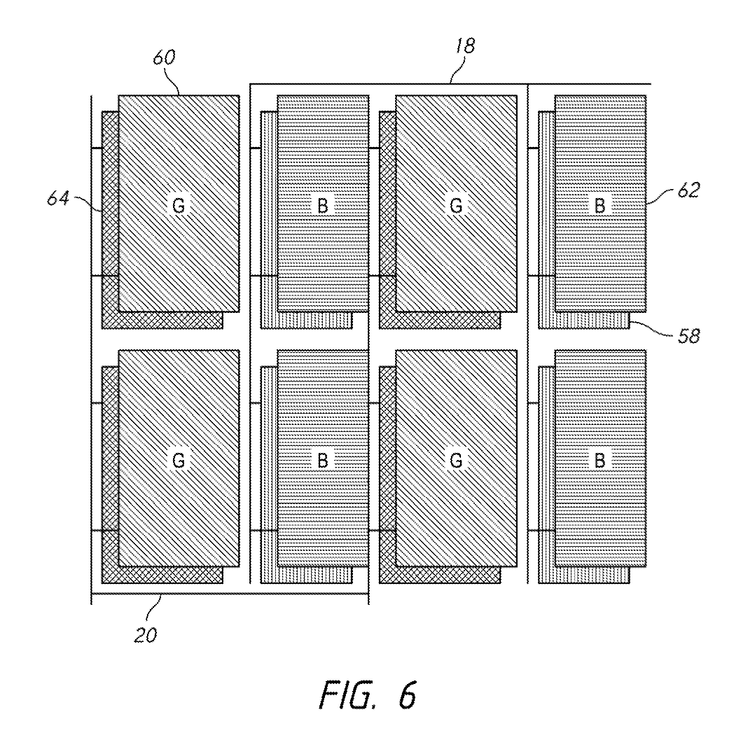

Example FIG. 6 illustrates a green pixel stacked over an infrared pixel and a blue pixel stacked over a red pixel, in accordance with embodiments.

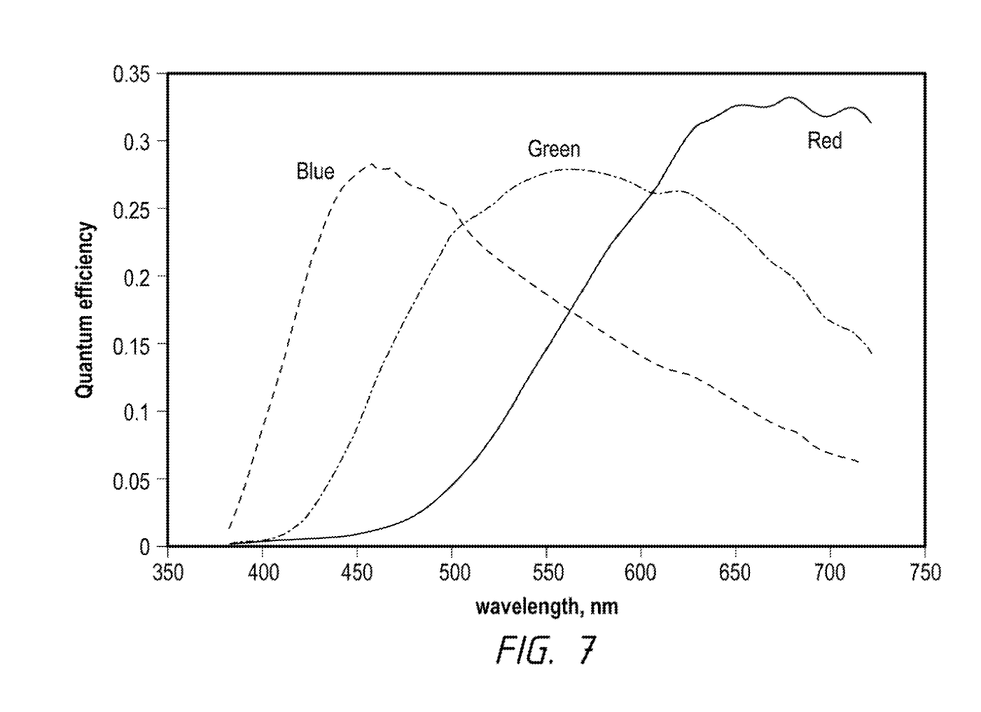

Example FIG. 7 is a diagram of wavelength versus quantum efficiency, in accordance with embodiments.

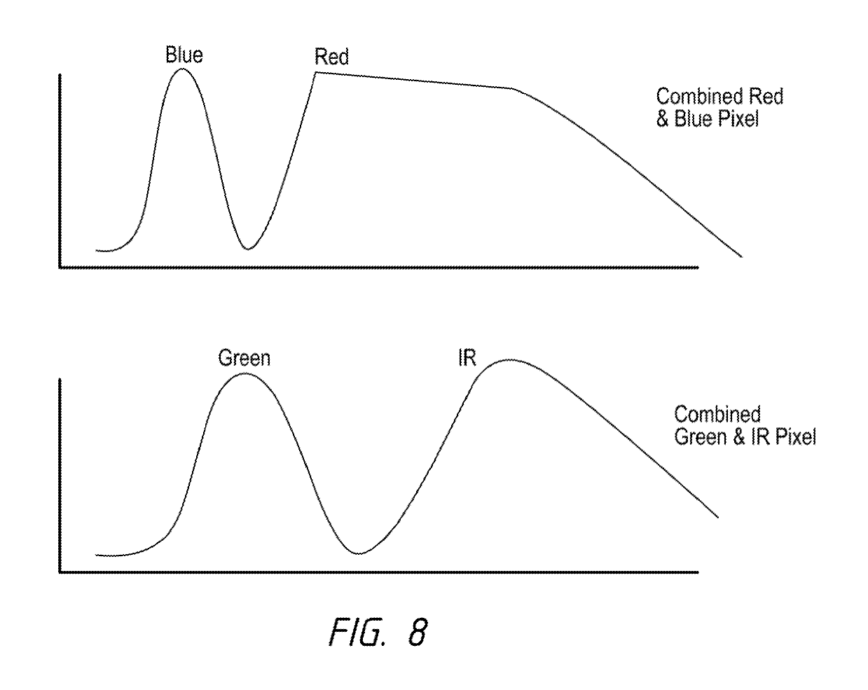

Example FIG. 8 is a diagram of color curves for sensor dyes, in accordance with embodiments.

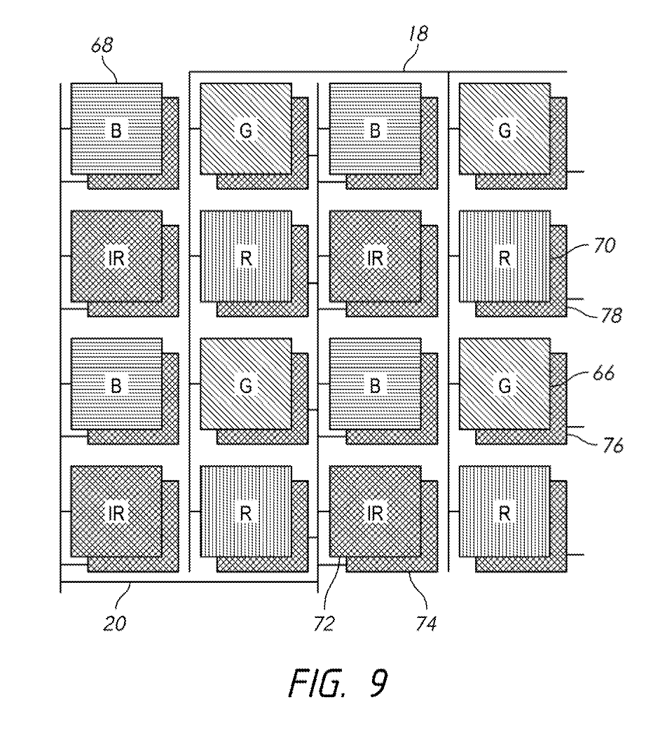

Example FIG. 9 illustrates lower infrared pixels stacked beneath each of red, green, blue, and upper infrared pixels, in accordance with embodiments.

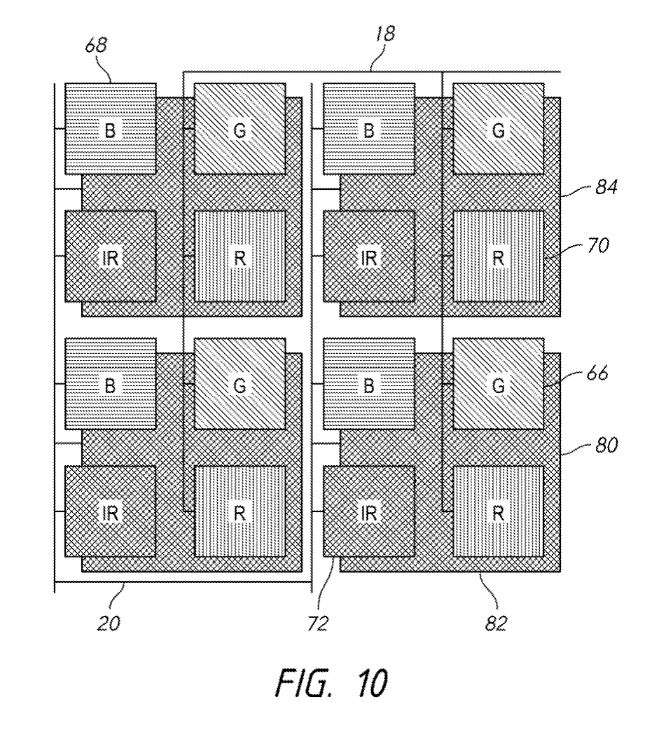

Example FIG. 10 illustrates a single relatively large lower infrared pixel stacked beneath a set of red, green, blue, and infrared pixels, in accordance with embodiments.

### DESCRIPTION

Example FIG. 1 illustrates an infrared (IR) pixel 16 that has a larger size than those of the red pixels 10 and green pixels 14, in accordance with embodiments. In embodiments, the IR pixels 16 may be approximately the same size as the blue pixels 12. The increase in the relative size of the IR pixel makes the IR pixel more sensitive to the IR light resulting in a better signal to noise ratio (SNR) than would smaller sized IR pixels. Control lines 20 may control the IR pixels 16 and the blue pixels 12, in accordance with embodiments. Control lines 18 may control the red pixels 10 and the green pixels 14, in accordance with embodiments.

Example FIG. 2 illustrates different patterns of infrared (IR) pixels mixed with visible light pixels (e.g. RGB pixels) where IR pixels (28, 34, 36, and 48) are larger than some of the red pixels (22, 38, and 42), green pixels (24, 30, 40, and 46), and blue pixels (26, 32, 44) of the RGB pixels, in accordance with embodiments. In the exemplary layouts illustrated in FIG. 2, the blue pixel size may be approximately the same size as the IR pixel. In embodiments, the green and red pixels may have higher responses than the blue pixels or IR pixels. The patterns illustrated in FIG. 2 are only examples and other patterns within the scope of embodiments can be configured similarly to boost relative infrared light sensitivity.

Although reference is made to the infrared, embodiments relate to attaining depth measurements through relative blurring by comparing the green channel to the red and blue channels or any other combination where a pixel has sensitivity to one region of the spectrum and there is an aperture which has a different size for that specific region. For example, if red light passes into an image sensor through a narrower aperture than for the blue and green light, various configurations of either stacking of pixels or having variations in size may be used to increase the sensitivity of the red channel to compensate for the narrower aperture for the red light, in accordance with embodiments.

Example FIG. 3 illustrates an arrangement where blue pixels 54 are stacked on top of the infrared pixels 56, in accordance with embodiments. In embodiments, the red pixels 50 and the green pixels 52 may be arranged adjacent to the stacked blue pixels 54 and infrared pixels 56. Related art image sensors (e.g. Foveon-type image sensors) make use of the fact that light penetrates different levels of depth into the silicon depending on the wavelength of the light. Infrared may penetrate most deeply into the silicon while blue may penetrate the silicon the least, depending on the material characteristics. Related art sensors based on penetration depth may have complications in that the separation of colors is difficult to process. For example, for visible light colors red, green, and blue, the overlap between the depth to which red penetrates and which green penetrates, for example, may be too significant to exhibit a clear boundary between green and red values for the pixel. Accordingly, there may be significant leakage between the pixel responses to different colors, which make it difficult to resolve into the two different colors.

Example FIG. 4 is a diagram that illustrates the penetration of visible light into a silicon wafer. Because blue light penetrate only to a relatively shallow depth into the silicon, while infrared penetrates relatively deep, there is a clear demarcation between the depth which the blue light penetrates the silicon and the depth to which the infrared light penetrates the silicon. In embodiments, the relative difference in penetration depth into silicon between blue light and infrared light is relatively large and therefore may be easy to compensate for.

In embodiments, the color discrimination based on the penetration depth may be applied to the blue pixels and infrared pixels due to the difference between the penetration depths. Infrared pixels may be placed below blue pixels and may be separated from the blue pixel by depth, in accordance with embodiments. The separation between the blue and infrared light may be relatively high due to the inability of the blue light to penetrate the silicon to the depth of the infrared pixels. The dye placed on the combined pixel may allow both infrared light and blue light to pass through, in accordance with embodiments.

One of the drawbacks of as RGBI pixel pattern (e.g. including red (R), green (G), blue (B), and infrared (I) pixels) in embodiments illustrated in FIGS. 1 and 2 are that one green pixel is replaced by the IR pixel compared to a related art RGB pixel array. Embodiments illustrated in FIG. 5 relate to a combination that increases the area of the green by having the green pixel combined with the infrared pixel. FIG. 5 illustrates an arrangement where a green pixel 60 is stacked over an infrared pixel 64, in accordance with embodiments. In embodiments, there is a significant distance between the green absorbing region 60 and the infrared absorbing region 64, which enables the color separation to be performed. In this embodiment, the blue pixel 58 and/or the red pixel 58 may be formed adjacent to the stacked green pixel 50 and infrared pixel 64.

FIG. 6 shows an arrangement with a red pixel 58 is stacked under a blue pixel 62 and a green pixel 60 stacked over an infrared IR pixel 64. A filter over the red pixel 58 and blue pixel 62 may substantially block the green light and infrared light from entering the red pixel 58 and blue pixel 62, in accordance with embodiments.

Example FIG. 7 illustrates as diagram of the quantum efficiency versus of different wavelength light, in accordance with embodiments. There are multiple ways that the stacked pixel techniques could be combined with the dual-aperture technique, in accordance with different embodiments. One of the challenges with the stacked pixel structure is that there is a significant overlap in sensitivity in color between each probe in the pixel. To overcome these and other challenges, embodiments may have only two different pixels each with a color combination that limits the overlap between the two colors, instead of stacking four different colors on as single pixel. In embodiments, for example, a blue pixel 62 and a red pixel 58 may overlap, as shown in example FIG. 6. In embodiments, a green pixel 60 and an infrared pixel 64 may overlap, as shown in example FIG. 6. The stacking of only two pixels, in accordance with embodiments, may reduce some of the difficulty of removing the color leakage that is normally associated with the stacked-type sensors.

Example FIG. 8 illustrates the color curves for stacked red pixels and blue pixels, in accordance with embodiments. Example FIG. 8 illustrates color curves for stacked green pixels and infrared pixels, in accordance with embodiments.

Embodiments relate to dual-well pixel where an infrared pixel is stacked beneath the RGBI pixels. In embodiments, there may be two wells for each of the visible light pixels (e.g. red, green, and blue) and the infrared pixels. The upper well may captures the visible light associated with pixel. The deeper well captures the IR light associated with the pixel. The color filter array may be in place on top of the pixel. The second well that is used to capture infrared is used to provide an additional sample of the infrared photons entering the pixel.

Example FIG. 9 illustrates a top view of dual-well pixels, in accordance with embodiments. For dual-well pixels, eight pixels can be used in the same area as four pixels for single well pixels, in accordance with embodiments. To improve sensitivity of infrared light passing through a relatively narrow aperture, there may be additional pixels detecting infrared light, in accordance with embodiments. For example, while in some embodiments there may be only one pixel per pixel set detecting infrared light, in other embodiments there may be multiple pixels detecting infrared in a pixel set. Multiple infrared sensors in a pixel set may allow for more refined measurements of infrared light than what is possible with only the dual-aperture color filter array without pixel stacking, in accordance with embodiments. Additional data and sensitivity of the infrared light should allow for greater noise reduction on infrared and better color accuracy in processing the image, in accordance with embodiments. In embodiments, infrared light may be compensated by creating a color correction matrix that builds an estimate for the infrared tight received from all 8 pixels using an 8×1 matrix, and then is subtracted from the visible light pixels before a 3×3 matrix is applied to the visible light pixels. In embodiments, infrared light may be compensated by creating an 8×3 matrix or an 8×4 matrix to generate a color correction for visible light and infrared light, which may be used for depth estimation algorithms. In embodiments, infrared light may enable the generation of good quality visible light image and then use a clean infrared channel that can be used for depth estimation.

Example FIG. 10 illustrates a single, large deep well for the four pixels RGBI pixel set, in accordance with embodiments. The configuration illustrated in example FIG. 10 may have the advantage of reducing the impact on read out time and reducing any impact that having additional wells has on the fill factor for the sensor, in accordance with embodiments. In embodiments, color correction may be a 5×1 matrix to estimate the infrared light which is subtracted from the visible light, followed by a 3×3 RGB color correction matrix. In embodiments, a 5×4 RGB color correction matrix, a 5×3 RGB color correction matrix, or other dimensions may be used.

In embodiments, pixel arrangement variation may influence interpolation used to fill in the missing colors for pixels in an image pattern. For example, with a Bayer pattern sensor, there may be a need for interpolating the missing color components for each pixel. For example, a red pixel in a related art RGGB pattern does not have green and blue values. These missing values for the red pixel are filled by interpolating the values of the adjacent green or blue pixels to create green and blue values for the pixel. This interpolation may be referred to as a demosaicing process, in accordance with embodiments.

For many of the designs described in this application, the demosaicing algorithm may require adaptation in accordance with embodiments. For example, in the case of the stacked pixels, before demosaicing each pixel has two values either (blue and red) or (green and IR). In this case, the demosaicing algorithm is only applied to the missing two colors for the pixel and not to the missing three colors for the pixel.

Although reference is made to compensating the narrow aperture of the IR, it is possible to achieve the depth measurement through relative blurring by comparing the green channel to the red channel or any other combination where a pixel has a sensitivity to one region of the spectrum and there is an aperture which has a different size for that specific region. Therefore, for example, in the case that the red channel has a narrower channel, any one of the above and the following techniques of either stacking of pixels or having variations in size may be used to increase the sensitivity of the red channel to compensate for the narrower aperture for the red channel.

Embodiments may apply to camera systems where there is the requirement for variations of sensitivity between different regions of light spectrum. For example, in a camera which is sensitive to infrared as well as RGB but does not use the dual-aperture lens system, it may be desirable to reduce the relative IR sensitivity by using a smaller pixel size for the IR pixel. This is possible due to the fact that the spectral width in the IR region is much larger than for the RGB regions. Alternatively, where there are requirements for different exposure timing settings on one region of the spectrum, it may also be desirable to have different sizes of pixel per color of region of the spectrum. Another reason for varying the relative sizing of the pixel may be to have different ISO or sensitivity of the pixel. These latter two techniques may be used for reducing blur due to camera shake or to enable more sophisticated noise reduction such as described in the Dual ISO case.

The aperture sizes may be matched to specific regions of the spectrum to the sensitivity of the pixel for that region, in accordance with embodiments. An objective for the design may be to ensure that under typical lighting conditions, the output level of each pixel associated with each part of the spectrum is of a similar magnitude. For example, if the aperture for one part of the spectrum reduces the light for that part of the spectrum by a factor of 4, the pixel for the corresponding part of the spectrum has its sensitivity increased by the same factor.

In the case of the double stacked pixels (Second IR Reference) there is an IR pixel beneath each RGB and infrared (IR) pixel. In this case, the demosaicing algorithm can be made more sophisticated. For instance, the image obtained from the bottom IR pixels can be high pass filtered to collect edge information. The same filtering is applied to the RGB and other IR pixels. The bottom IR pixel values are then weighted to match the edge information in the corresponding RGB and IR pixels that lie above the bottom IR pixels. This may (in embodiments) involve changing both the phase and magnitude information of the edge information. These values that have been adjusted are then used to fill in the missing values for the respective pixels by adding them to the average value for pixels near to the pixel which have captured the missing color. For example in a red pixel, the average value of surrounding green pixels is computed, the bottom IR pixel value is adjusted in magnitude to match the green levels and then added to the average of the surrounding green pixels.

It is to be understood that the above descriptions are only illustrative only, and numerous other embodiments can be devised, without departing the sprit and scope of the disclosed embodiments. It will be obvious and apparent to those skilled in the art that various modifications and variations can be made in the embodiments disclosed, with the claim scope claimed in plain language by the accompanying claims.

What is claimed is:

1. An apparatus comprising:
an image sensor comprising as plurality of different types of image sensor pixels responsive to different wavelength of light; and
as first aperture configured to pass a first wavelength range of light onto the image sensor through the first aperture, wherein the first aperture has a first aperture width;
as second aperture configured to pass a second wavelength range of light onto the image sensor through the second aperture, wherein the second wavelength range of light is different than the first wavelength range of light, and wherein the width of the first aperture is larger than the width of the second aperture,
wherein the plurality of different types of image sensor pixels are arranged to compensate for the sensitivity of the first wavelength range of light onto the image sensor relative to the sensitivity of the second wavelength range of light onto the image sensor.

2. The apparatus of claim 1, wherein the plurality of different types of image sensors are arranged with different surface areas to compensate for the sensitivity of the first wavelength of range of light relative to the sensitivity of the second wavelength range of light onto the image sensor.

3. The apparatus of claim 1, wherein at least two of the plurality of different types of image sensors are arranged at different depths within an image sensor silicon substrate to compensate for the sensitivity of the first wavelength range of light relative to the sensitivity of the second wavelength range of light onto the image sensor.

4. The apparatus of claim 3, wherein a first type of image sensor pixels sensitive to the first wavelength range of light are formed above a second type of image sensor pixels sensitive to the second wavelength range of light in the silicon substrate.

5. The apparatus of claim 4, wherein the first type of image sensor pixel is sensitive to red light within the first wavelength range of light.

6. The apparatus of claim 4, wherein the first type of image sensor is sensitive to green light within the first wavelength range of light.

7. The apparatus of claim 4, wherein the first type of image sensor is sensitive to blue light within the first wavelength range of light.

8. The apparatus of claim 4, wherein the second type of image sensor is sensitive to infrared light within the second wavelength range of light.

9. The apparatus of claim 4, wherein the second type of image sensor is sensitive to red light within the second wavelength range of light.

10. The apparatus of claim 1, wherein the first wavelength range comprises visible light.

11. The apparatus of claim 1, wherein:
the plurality of different types of image sensors comprises red pixels, green pixels, and blue pixels configured to be responsive to the first wavelength range of light and the plurality of different types of image sensor comprises at least one of infrared pixels or red pixels configured to be responsive to the second wavelength range of light.

12. A method comprising:
passing a first wavelength range of light through a first aperture onto a first type of image sensor pixels, wherein the first aperture has a first aperture width;
passing a second wavelength range of light through a second aperture onto a second type of image sensor pixels, wherein the second wavelength range of light is different than the first wavelength range of light, and wherein the width of the first aperture is larger than the width of the second aperture,
wherein the plurality of different types of image sensor pixels are arranged to compensate for the sensitivity of the first wavelength range of light onto the image sensor relative to the sensitivity of the second wavelength range of light onto the image sensor.

13. The method of claim 12, wherein the first type of image sensor pixels are arranged with different surface areas than the second type of image sensor pixels to compensate for the sensitivity of the first wavelength range of light relative to the sensitivity of the second wavelength range of light onto the image sensor.

14. The method of claim 12, wherein the first type of image sensor pixels are arranged at different depths within an image sensor silicon substrate than the second type of image sensor pixels to compensate for the sensitivity of the first wavelength range of light relative to the sensitivity of the second wavelength range of light onto the image sensor.

15. The method of claim 12, wherein the first type of image sensor pixel is sensitive to red light within the first wavelength range of light.

16. The method of claim 12, wherein the first type of image sensor is sensitive to green light within the first wavelength range of light.

17. The method of claim 12, wherein the first type of image sensor is sensitive to blue light within the first wavelength range of light.

18. The method of claim 12, wherein the second type of image sensor is sensitive to infrared light within the second wavelength range of light.

19. The method of claim 12, wherein the second type of image sensor is sensitive to red light within the second wavelength range of light.

20. The method of claim 12, wherein:
the first type of image sensor pixels comprises red pixels, green pixels, and blue pixels configured to be responsive to the first wavelength range of light; and
the second type of image sensor pixels comprises at least one of infrared pixels or red pixels configured to be responsive to the second wavelength range of light.
